(19) United States
(12) Patent Application Publication
(10) Pub. No.: US 2021/0307161 A1
(43) Pub. Date: Sep. 30, 2021

(54) FLEXIBLE DIELECTRIC MATERIAL COMPRISING A BIAXIALLY-ORIENTED POLYTETRAFLUOROETHYLENE REINFORCING LAYER

(71) Applicant: Rogers Corporation, Chandler, AZ (US)

(72) Inventors: John Thomas Neill, Woodstock, CT (US); Rebecca Agapov, Bear, DE (US); Matthew Raymond Himes, Bear, DE (US)

(21) Appl. No.: 17/210,722

(22) Filed: Mar. 24, 2021

Related U.S. Application Data
(60) Provisional application No. 63/000,857, filed on Mar. 27, 2020.

(51) Int. Cl. H05K 1/03; H05K 3/46

(52) U.S. Cl. CPC H05K 1/036; H05K 1/0281; H05K 3/4688

(57) ABSTRACT

In an aspect, a circuit material comprises a multilayer stack comprising alternating layers of a reinforcing layer and a fluoropolymer layer; wherein the fluoropolymer layer comprises a fluoropolymer other than a biaxially-oriented polytetrafluoroethylene; wherein the reinforcing layer comprises a biaxially-oriented polytetrafluoroethylene; and wherein an conductive layer is in direct physical contact with an outer surface of the multilayer stack. In another aspect, an article comprises the circuit material. In yet another aspect, a method of making the circuit material comprises laminating the multilayer stack and the conductive layer to form the circuit material; or laminating a layered stack comprising the conductive layer and alternative layers of the fluoropolymer layers and the reinforcing layer to form the circuit material.

### CROSS-REFERENCE TO RELATED APPLICATION

This application claims the benefit of U.S. Provisional Patent Application Ser. No. 63/000,857 filed Mar. 27, 2020. The related application is incorporated herein in its entirety by reference.

### BACKGROUND

This disclosure is related to circuit materials, in particular circuit materials including a biaxially-oriented polytetrafluoroethylene reinforcing layer.

Flexible circuit materials are typically created from expensive, ultra-high temperature materials such as liquid crystal polymers (LCP) or polyimides (PI). These materials can suffer from difficulty in processing (LCP), or high moisture pick-up, causing dielectric constant drift (PI). Improved flexible circuit materials are therefore desired.

### BRIEF SUMMARY

Disclosed herein is a flexible dielectric material comprising a biaxially-oriented polytetrafluoroethylene reinforcing layer.

In an aspect, a circuit material comprises a multilayer stack comprising alternating layers of a reinforcing layer and a fluoropolymer layer; wherein the fluoropolymer layer comprises a fluoropolymer other than a biaxially-oriented polytetrafluoroethylene; wherein the reinforcing layer comprises a biaxially-oriented polytetrafluoroethylene; and wherein a conductive layer is in direct physical contact with an outer surface of the multilayer stack.

In another aspect, an article comprises the circuit material.

In yet another aspect, a method of making the circuit material comprises laminating the multilayer stack and the conductive layer to form the circuit material; or laminating a layered stack comprising the conductive layer and alternating layers of the fluoropolymer layers and the reinforcing layer to form the circuit material.

The above described and other features are exemplified by the following figures, detailed description, and claims.

### BRIEF DESCRIPTION OF THE DRAWINGS

The following Figures are exemplary aspects, which are provided to illustrate the present disclosure.

FIG. 1 is an illustration of an aspect of the flexible circuit material; and

FIG. 2 is an illustration of another aspect of the flexible circuit material.

### DETAILED DESCRIPTION

Circuit materials comprising fluoropolymer dielectric layers can experience warpage in reflow soldering due to the large differences in the coefficient of thermal expansion between the fluoropolymer and a neighboring conductive layer, for example, an electrically conductive layer. Woven and non-woven fabrics, in particular glass fabrics such as E-glass have been incorporated into fluoropolymer dielectric layers in order to reduce this effect. Such incorporation adds additional costs and fabrication steps. An improved dielectric material was developed comprising a biaxially-oriented polytetrafluoroethylene reinforcing layer (referred to herein as the reinforcing layer). The dielectric material has the benefit in that the reinforcing layer can be free of a woven or non-woven fabric. Instead, the biaxially-oriented polytetrafluoroethylene itself provides the reinforcing properties. Moreover, the circuit material has improved mechanical properties, for example, at least one of an improved yield strength, improved flexibility, and desirable dielectric properties.

The circuit material can include a multilayer stack comprising at least one reinforcing layer and at least one fluoropolymer layer. The reinforcing layer can be located in between two fluoropolymer layers. For example, the multilayer stack can comprise at least one reinforcing layer located in between a first fluoropolymer layer and a second fluoropolymer layer, where at least the first fluoropolymer layer is an outermost layer of the multilayer stack. The first fluoropolymer layer and the second fluoropolymer layer can be in direct physical contact with the reinforcing layer. Conversely, the fluoropolymer layer can be located in between a first reinforcing layer and a second reinforcing layer, where at least the first reinforcing layer is an outermost layer of the multilayer stack. The first reinforcing layer and the second reinforcing layer can be in direct physical contact with the fluoropolymer layer. The multilayer stack can comprise multiple fluoropolymer layers alternating with multiple reinforcing layers.

The circuit material can further include at least one outer conductive layer that can be in direct physical contact with an outer surface of the multilayer stack, for example, with an outer surface of a first fluoropolymer layer opposite a reinforcing layer or a first reinforcing layer opposite a fluoropolymer layer. A second conductive layer can be in direct physical contact with an opposing side of the multilayer stack, for example, with an opposing fluoropolymer layer of the multilayer stack or an opposing reinforcing layer. In an aspect, no LCP or PI layer is present in the circuit material. In another aspect, no polymer layer other than an optional adhesive layer, the at least one reinforcing layer and the at least one fluoropolymer layer are present. In another aspect, no polymer layer other the at least one reinforcing layer and the at least one fluoropolymer layer are present.

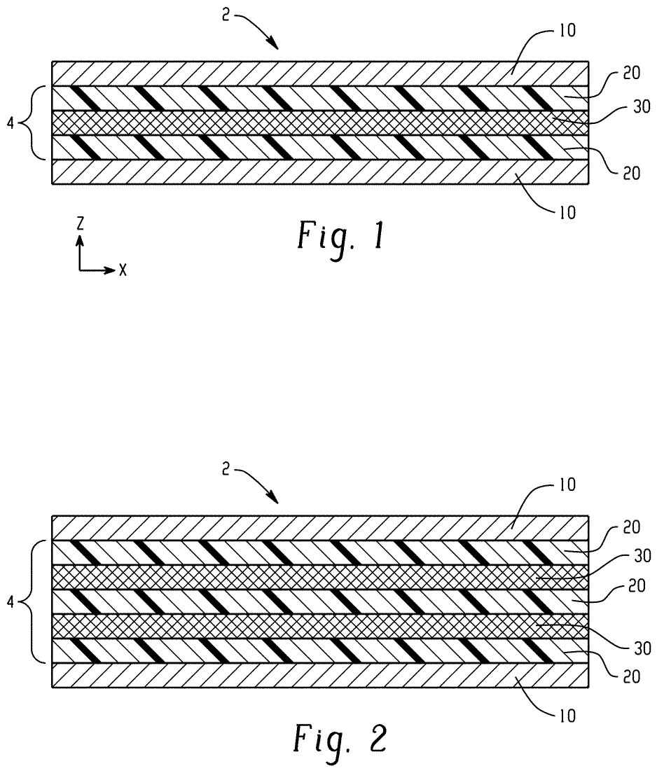

FIG. 1 and FIG. 2 are non-limiting illustrations of a circuit material 2. FIG. 1 shows a multilayer stack 4 including a reinforcing layer 30 located in between two fluoropolymer layers 20. The multilayer stack 4 is located in between two outer conductive layers 10, wherein at least one, and preferably both of the outer conductive layers is electrically conductive. The other outer conductive layer can be electrically conductive, thermally conductive, or both. FIG. 2 shows another illustration of a circuit material 2, where the multilayer stack 4 includes two reinforcing layers 30 alternating with three fluoropolymer layers 20. The multilayer stack 4 having outer fluoropolymer layers 20 is located in between two outer conductive layers 10 wherein at least one, preferably both of the conductive layers are electrically conductive. It is noted that in the multilayer stack 4, the reinforcing layers 30 and the fluoropolymer layers 20 can be reversed so that outer layers are the reinforcing layers 20. It is further noted that, although not illustrated, one of the outer layers of the multilayer stack 4 can be a reinforcing layer 30 and the other of the outer layers can be a fluoropolymer layer 20.

The multilayer stack can comprise alternating layers of the reinforcing layers and fluoropolymer layers. The number of fluoropolymer layers can be at least one more than the number of reinforcing layers and where there is at least one reinforcing layer present. The number of reinforcing layers can be at least one more than the number of fluoropolymer layers and where there is at least one fluoropolymer layer present. The number of reinforcing layers can be the same as the number of fluoropolymer layers. The multilayer stack can include 1 to 100 of one of the reinforcing layers or the fluoropolymer layers, or 1 to 20, or 1 to 5 layers. The multilayer stack can include 1 to 100 of the other of the reinforcing layers or the fluoropolymer layers, or 2 to 101 layers, or 2 to 211, or 2 to 6 layers. The multilayer stack can include n number of one of the reinforcing layers or the fluoropolymer layers and (n+1) number of one of the other of the reinforcing layers or the fluoropolymer layers, wherein n can be 1 to 100, or 1 to 20, or 1 to 5.

A total thickness of the circuit material including the conductive layer(s) (for example, in the z-direction illustrated in FIG. 1) of 25 to 150 micrometers, or 25 to 200 micrometers.

The fluoropolymer layers each independently comprise a fluoropolymer other than a biaxially-oriented polytetrafluoroethylene (biaxially-oriented PTFE). The fluoropolymer can have a melting temperature of 320 to 400° C., or 350 to 400° C. Within this range, melting of the fluoropolymer can be achieved without melting the crystal structure of the biaxially-oriented polytetrafluoroethylene in the reinforcing layer during fabrication. The fluoropolymer can comprise at least one of poly(chlorotrifluoroethylene) (PCTFE), poly(chlorotrifluoroethylene-propylene), poly(ethylene-tetrafluoroethylene) (ETFC), poly(ethylene-chlorotrifluoroethylene) (ECTFE), poly(hexafluoropropylene), poly(tetrafluoroethylene-ethylene-propylene), poly(tetrafluoroethylene-hexafluoropropylene) (also known as fluorinated ethylene-propylene copolymer (FEP)), poly(tetrafluoroethylene-propylene) (also known as fluoroelastomer) (FEPM), poly(tetrafluoroethylene-perfluoropropylene vinyl ether), polyvinylfluoride (PVF), polyvinylidene fluoride (PVDF), poly(vinylidene fluoride-chlorotrifluoroethylene), perfluoropolyether, perfluorosulfonic acid, or perfluoropolyoxetane. The fluoropolymer can comprise at least one of FEP or PFA, which can be fibril forming or non-fibril forming. The fluoropolymer can comprise a perfluoroalkoxy alkane polymer (PFA). FEP is available under the trade TEFLON FEP from DuPont or NEOFLON FEP from Daikin. PFA is available under the trade name NEOFLON PFA from Daikin, TEFLON PFA from DuPont, or HYFLON PFA from Solvay Solexis.

The fluoropolymer layer(s) and the reinforcing layer(s) can each independently be free of a void space.

The fluoropolymer layer(s) can each independently have a thickness in the final composite (for example, in a z-direction as illustrated in FIG. 1) of 2 to 70 micrometers, or 2 to 60 micrometers, or 3 to 50 micrometers. The respective fluoropolymer layers can each independently comprise a stack of two or more fluoropolymer layers (otherwise known as plies).

At least one of the fluoropolymer layers can comprise a dielectric filler. The dielectric filler can comprise at least one of silica (for example, fused amorphous silica), wollastonite, solid glass spheres, synthetic glass or ceramic hollow spheres, quartz, boron nitride, aluminum nitride, silicon carbide, alumina trihydrate, magnesia, mica, talc, nanoclay, or magnesium hydroxide. The fluoropolymer layer can comprise silica when a circuit material with low loss is desired. The fluoropolymer layer can comprise titania when a circuit material with higher permittivity is desired. The dielectric filler can be present in an amount of 10 to 75 volume percent (vol %), or 30 to 70 vol % based on the total volume of the respective fluoropolymer layers. The dielectric filler can have an average outer diameter of less than or equal to 40 micrometers, or 1 to 35 micrometers, or 1 to 10 micrometers. The size distribution of the dielectric filler can be bimodal, trimodal, or the like.

The dielectric filler can be surface-treated (also referred to herein as coated) to aid dispersion into the respective layer, for example, with at least one of a surfactant (such as oleylamine oleic acid), an inorganic material (such as SiO₂, Al₂O₃, and MgO), a silane, a titanate, or a zirconate. The coating can comprise at least one of a silane coating, a titanate coating, or a zirconate coating. The coating can comprise at least one of phenyltrimethoxysilane, p-chloromethylphenyltrimethoxy silane, aminoethylaminotrimethoxy silane, aminoethylaminopropyltrimethoxy silane, phenyltriethoxysilane, 3,3,3-trifluoropropyl trimethoxysilane, (tridecafluoro-1,1,2,2-tetrahydrodecyl)-1-triethoxysilane, neopentyl(diallyl)oxytrineodecanoyl titanate, neopentyl(diallyl)oxytri(dioctyl)phosphate titanate, neopentyl(diallyl)oxytri(dioctyl)pyrophosphate zirconate, or neopentyl(diallyl) oxytri(N-ethylenediamino)ethyl zirconate. The coating can comprise a silane coating comprising at least one of an aromatic silane such as phenyltrimethoxysilane or a fluorinated aliphatic alkoxysilane such as (tridecafluoro-1,1,2,2-tetrahydrooctyl)triethoxysilane.

The dielectric filler can be pretreated with the coating agent prior to forming a composite mixture with the respective polymer, or the coating agent can be added to the composite mixture prior to forming the respective layer. The coating can be present in an amount of 0.2 to 4 weight percent (wt %), or 1 to 3 wt % based on the total weight of the dielectric filler.

The fluoropolymer layer(s) can be prepared by mixing the fluoropolymer and an optional dielectric filler in an aqueous solvent, for example, in water to form a mixture. The mixture can then be cast onto a release liner and dried to form the fluoropolymer layer. The fluoropolymer layer(s) can comprise one or more individual plies of the fluoropolymer, for example, 1 to 100 plies that can be laminated together to form the fluoropolymer layer.

The reinforcing layer comprises biaxially-oriented PTFE. The biaxially-oriented PTFE can have an initial porosity of greater than or equal to 50 vol %, or 50 to 90 vol %, or 75 to 95 vol % based on the total volume of the reinforcing layer prior to laminating. The porosity can be determined via a density calculation or via xylene uptake measurements. The pores or void space can be open, such that air can flow from one surface of the reinforcing layer to the opposite surface of the reinforcing layer through the pores of the reinforcing layer. An average channel width can be small enough to prevent any of the fluoropolymer from entering the reinforcing layer during formation of the multilayer structure or of the circuit material. After lamination, the reinforcing layer can be free of a void space, for example, as evaluated using scanning electron microscopy to show no visible void space. In other words, the porosity of the reinforcing layer in the circuit material can be 0 to 1 vol %, or 0 vol % based on the total volume of the reinforcing layer.

The reinforcing layer can comprise one or more plies of the reinforcing layer, for example, 1 to 100 plies that can be laminated to form the reinforcing layer. The reinforcing layer is free of a woven or non-woven cloth such as a glass cloth. Likewise, the reinforcing layer is free of a fibrous layer, where only PTFE fibers can be present in the reinforcing layer. It is noted however that after laminating, PTFE fibers may not be visible using scanning electron microscopy in the reinforcing layer. The reinforcing layer can consist of the biaxially-oriented PTFE and an optional filler. The optional filler can comprise at least one of a dielectric filler (for example, as described above) or a plurality of hollow microspheres. The hollow microspheres can comprise at least one of ceramic hollow microspheres, polymeric hollow microspheres, or glass hollow microspheres (such as those made of an alkali borosilicate glass). The hollow microspheres can have an average outer diameter of less than or equal to 100 micrometers, or 10 to 100 micrometers, or 20 to 70 micrometers, or 30 to 65 micrometers, or 40 to 55 micrometers, or 35 to 60 micrometers. The size distribution of the hollow microspheres can be bimodal, trimodal, or the like.

The filler can be present in the reinforcing layer in an amount of 1 to 60 vol %, or 10 to 50 vol % based on the total volume of the reinforcing layer on a void-free basis.

A thickness of the reinforcing layer, as received (for example, before lamination), can be 3 to 60 micrometers, or 10 to 100 micrometers.

The biaxially-oriented PTFE includes polytetrafluoroethylene (PTFE) having a void space. The PTFE can comprise at least one of a homopolymer or a trace modified homopolymer. As used herein, a trace modified PTFE homopolymer comprises less than 1 wt % of a repeat unit derived from a co-monomer other than tetrafluoroethylene based on the total weight of the PTFE. The PTFE can be polymerized by emulsion polymerization to form a dispersion that can be further coagulated to form a coagulated dispersion or fine powder PTFE. The reinforcing layer can be formed from the coagulated dispersion for fine powder via paste extrusion and calendering. Alternatively, the PTFE can be polymerized by suspension polymerization to form a granular PTFE. A reinforcing layer comprising a coagulated dispersion or fine powder PTFE formed by paste extrusion and calendering can be less brittle as compared to a substrate of the same composition but comprising a granular PTFE.

The circuit material can comprise a multilayer stack comprising alternating layers of at least one reinforcing layer and at least one fluoropolymer layer; wherein the fluoropolymer layer comprises a fluoropolymer other than a biaxially-oriented polytetrafluoroethylene; wherein the reinforcing layer comprises a biaxially-oriented polytetrafluoroethylene; and wherein an conductive layer is in direct physical contact with an outer surface of the multilayer stack. The reinforcing layer can be located in between a fluoropolymer layer and an additional fluoropolymer layer; wherein at least the fluoropolymer layer can be an outermost layer of the multilayer stack; wherein the conductive layer can be in direct physical contact with an outer surface of the fluoropolymer layer opposite the reinforcing layer. The fluoropolymer layer can be located in between the reinforcing layer and an additional reinforcing layer; wherein the reinforcing layer can be an outermost layer of the multilayer stack; wherein the conductive layer can be in direct physical contact with an outer surface of the reinforcing layer opposite the fluoropolymer layer. The multilayer stack can comprise n number of reinforcing layers and (n+1) number of fluoropolymer layers or wherein the multilayer stack comprises n number of fluoropolymer layers and (n+1) number of reinforcing layers, wherein n is 1 to 100. The fluoropolymer can have a melting temperature of 320 to 400° C., or 350 to 400° C. The multilayer stack can comprise more than one fluoropolymer layers and the respective fluoropolymer layers can each independently have a thickness of 2 to 70 micrometers, or 2 to 60 micrometers, or 3 to 50 micrometers. The respective layers in the multilayer stack can each independently comprise a dielectric filler, wherein the multilayer stack comprises more than one fluoropolymer layers and wherein the respective fluoropolymer layers each independently have a thickness of 2 to 70 micrometers, or 2 to 60 micrometers, 3 to 50 micrometers, optionally in an amount of 10 to 75 vol %, or 30 to 70 vol % based on the total volume of the respective layers. The reinforcing layer can have a thickness of 3 to 25 micrometers, or 1 to 80 micrometers. The circuit material can have a total thickness of 25 to 150 micrometers, or 25 to 200 micrometers.

The fluoropolymer can comprise at least one of poly(chlorotrifluoroethylene) (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene-ethylene-propylene), poly(tetrafluoroethylene-hexafluoropropylene) (also known as fluorinated ethylene-propylene copolymer (FEP)), poly(tetrafluoroethylene-propylene), poly(tetrafluoroethylene-perfluoropropylene vinyl ether), polyvinylfluoride (PVF), polyvinylidene fluoride (PVDF), poly(vinylidene fluoride-chlorotrifluoroethylene), perfluoropolyether, perfluorosulfonic acid, or perfluoropolyoxetane. The fluoropolymer can comprise a perfluoroalkoxy alkane polymer (PFA). The dielectric filler can comprise at least one of silica, wollastonite, solid glass spheres, synthetic glass or ceramic hollow spheres, quartz, boron nitride, aluminum nitride, silicon carbide, alumina trihydrate, magnesia, mica, talc, nanoclay, or magnesium hydroxide; or wherein the dielectric filler can comprise at least one of silica or titania. The reinforcing layer can comprise a plurality of hollow microspheres. The reinforcing layer can be free of a woven or non-woven cloth such as a glass cloth. The circuit material can further comprise a second conductive layer in direct physical contact with an opposing surface of the multilayer stack opposite from the conductive layer. The conductive layer can comprise a copper foil.

The reinforcing layer can be prepared by forming a sheet and calendering the sheet to form the reinforcing layer. The reinforcing layer can be formed by paste extruding a lubricated crumb comprising PTFE, a lubricant, and the optional filler. Examples of lubricants include ISOPAR commercially available from Exxon Chemical Company, Houston, Tex. The mixing can comprise mixing in a tumble mixer that rotates 360° in the vertical direction. The lubricated crumb can be formed by mixing the PTFE, the optional filler, and the lubricant. The mixing can comprise first mixing the PTFE, then adding the optional filler, and lastly mixing in the lubricant. The mixing can comprise assisted mixing, for example, with a stir bar optionally having one or more mixing blades. A commercially available example of a mixer having a stir bar is a Patterson Kelly Vee-Blender with an intensifier bar. The mixing can comprise first mixing the PTFE and the optional filler in an air mill. A commercially available example of an air mill is the Jet Pulverizer Micron-Master mill. The air milled powder can allow for higher filler loadings without the article becoming brittle. The mixing can occur for 4 to 100 minutes, or 10 to 50 minutes.

The lubricated crumb can be heated prior to forming the sheet, for example, at a temperature of 40 to 150 degrees Celsius (° C.) for 1 to 40 hours. The sheet can be formed by paste extrusion. The paste extrusion can occur at a temperature of 15 to 150° C., or 40 to 60° C. The sheet can be formed by compression molding.

The sheet can be calendered to form the reinforcing layer. The calendering can comprise a single calendering step or multiple calendering steps. For example, the sheet can be subjected to an initial calendering step, wherein the sheet is passed through at least one set of opposing stainless steel calendering rolls, which have an adjustable gap thickness there between. The gap thickness between the rolls can be adjusted to decrease the thickness of the sheet as it passes between them. During the calendering, the width of the sheet will be maintained, but the length of the sheet increases as the thickness decreases. One example of a commercially available calendering machine is the small Killion two-roll stack (Killion Extruders, Inc., Cedar Grove, N.J., 07009). The sheet can then be further calendered in one or more calendering steps, for example, at an angle of 45 to 135°, for example, 90° of the initial calendering direction. The calender rolls can be heated, for example, to a temperature of 40 to 150° C., or 45 to 60° C.

After calendering, the reinforcing layer can be soaked in water and/or heated, for example, the reinforcing layer can be soaked for 10 to 60 minutes, or 15 to 20 minutes to remove any solvent and/or heated at a temperature of 150 to 300° C., or 50 to 300° C., or 200 to 300° C. for 1 to 40 hours, or 5 to 15 hours. After heating, the reinforcing layer can comprise less than or equal to 0.2 wt %, or 0 to 0.1 wt % of the lubricant based on the total weight of the reinforcing layer.

The reinforcing layer can be formed by casting. For example, the casting can comprise casting an aqueous dispersion comprising the PTFE, the optional filler, a liquid carrier, and an optional viscosity modifier onto a carrier sheet; drying the cast dispersion; sintering to form a sheet; and removing from the carrier sheet. The liquid carrier can comprise water. The optional viscosity modifier can comprise at least one of polyacrylic acid, methyl cellulose, polyethylene oxide, guar gum, locust bean gum, sodium carboxymethylcellulose, sodium alginate, or gum tragacanth. The method can comprise multiple casting steps to result in an increased thickness of the sheet. After the casting, the cast dispersion can be heated to a first temperature to dry form a dried sheet, for example, at a temperature of 150 to 300° C. The dried sheet can then be sintered to form the reinforcing layer, for example, by sintering at a sintering temperature of 350 to 400° C. The casting can be performed in accordance with U.S. Pat. No. 5,506,049.

The reinforcing layer can be formed by molding. For example, the molding can comprise mixing a molding mixture comprising a granular PTFE and the optional filler (for example, by air milling), molding the mixture, and optionally calendering. The mixing can comprise intensively mixing the molding mixture in order to achieve a uniform molded part with good physical properties. For example, mixing the molding mixture can comprise mixing by powder blending and an additional high intensity mixing step. The high intensity mixing can include passing the mixture through an air mill, such as the Micron-Master air mill, made by the Jet Pulverizer Company of Moorestown, N.J., the SpeedMixer bladeless mixer made by FlackTek of Landrum, S.C., or dry blending in a Vee Blender with an intensifier bar. After intensive mixing, the molding mixture can be compression molded or dry calendered.

The circuit material can have at least one conductive layer disposed thereon. At least one surface of each conductive layer independently can be in direct physical contact with a fluoropolymer layer. Useful conductive layers include, for example, at least one of stainless steel, copper, gold, silver, aluminum, zinc, tin, lead, or a transition metal. There are no particular limitations regarding the thickness of the conductive layer, nor are there any limitations as to the shape, size, or texture of the surface of the conductive layer. The conductive layer can have a thickness of 3 to 200 micrometers, or 9 to 180 micrometers. When two or more conductive layers are present, the thickness of the two layers can be the same or different. The conductive layer can comprise a copper layer. Suitable conductive layers include a thin layer of a conductive metal such as aluminum, copper, or an alloy thereof, e.g., a copper foil presently used in the formation of circuits, for example, an electrodeposited copper foil.

The electrically conductive layer can include a copper foil. The copper foil can have a root mean squared (RMS) roughness of less than or equal to 5 micrometers, or 0.1 to 3 micrometers, or 0.05 to 0.7 micrometers. As used herein, the roughness of the electrically conductive layer can be determined by atomic force microscopy in contact mode, reporting the Rz in micrometers calculated by determining the sum of five highest measured peaks minus the sum of the five lowest valleys and then dividing by five (JIS (Japanese Industrial Standard)-B-0601); or the roughness can be determined using white light scanning interferometry in contactless mode and is reported as Sa (arithmetical mean height), Sq (root mean square height), Sz (maximum height) height parameters in micrometers using a stitching technique to characterize treated-side surface topography and texture (ISO 25178). The copper foil can be a battery foil layer having a zinc free low profile treated side roughness, for example, having at least one of an Sa of 0.05 to 0.4 micrometers, an Sq of 0.01 to 1 micrometers, an Sz of 0.5 to 10 micrometers.

A thickness of each conductive layer independently can be 0.005 to 0.05 millimeters, or 0.01 to 0.03 millimeters.

When one of the layers is a thermally conductive layer, the thickness can be greater, provided that the flexibility of the circuit material is not substantially adversely affected.

The method of making the circuit material is not particularly limited. For example, a method of making the circuit material can comprise first laminating a layered stack including alternative layers of the fluoropolymer layers and the reinforcing layer to form the multilayer stack; and then laminating the multilayer stack to at least one outer conductive layer. Conversely, the circuit material can be formed in a single laminating step, laminating a layered stack comprising the multilayer stack including alternative layers of the fluoropolymer layers and the reinforcing layer and at least one outer conductive layer. The laminating step(s) can comprise placing a layered structure in a press, e.g., a vacuum press, under a pressure and temperature and for a duration of time suitable to bond the layers and form the circuit material. The laminating step(s) can occur at a lamination temperature of 340 to 400° C., or 350 to 380° C. The laminating step(s) can occur at a lamination pressure of 2 to 10 megapascal, or 3 to 8 megapascal. The laminating step(s) can occur for a lamination time of 50 to 120 minutes, or 75 to 100 minutes. The laminating can comprise a continuously laminating, for example, using a roll to roll process.

Prior to laminating, one or more of the surfaces of the fluoropolymer layers or the reinforcing layer can be irradiated with ionizing radiation to promote covalent bonding between the respective layers. Prior to laminating, one or more of the surfaces of the fluoropolymer layers or the conductive layer can be irradiated with ionizing radiation in the absence of oxygen to promote covalent bonding between the respective layers. The irradiating can occur in an oxygen free environment, for example, comprising less than or equal to 200 parts per million by weight of oxygen.

The circuit material can have a permittivity of greater than or equal to 2, or 2 to 5. The circuit material can have a dielectric loss of less than or equal to 0.003, or 0.0005 to 0.0025. The dielectric properties are determined in accordance with IPC-TM-650 2.5.5.5 Stripline Test for Permittivity and Loss Tangent at X-Band method at 10 gigahertz (GHz).

The circuit material can have a peel strength to copper of greater than or equal to 3.0 pounds per linear inch (PLI) (0.53 Newtons per millimeter (N/mm)), or 3.0 to 6.0 PLI (0.54 to 1.07 N/mm) as measured in accordance with the IPC test method 650 2.4.8.

The circuit material can have a coefficient of thermal expansion of 15 to 100 parts per million per degree Celsius (ppm/° C.) in the X- or Y-direction as determined in accordance with IPC-TM-650 2.4.41 from 0 to 150° C.

The circuit material can have good mechanical properties such that it can be temporarily flexed to allow positioning within a device without cracking, crazing, or delaminating of one or more of the layers. The circuit material can have a yield point in the machine direction (MD) of greater than or equal to 20 megapascal (MPa), or 20 to 100 MPa, or 20 to 50 MPa. The circuit material can have a yield point in the cross machine direction (CMD) of greater than or equal to 20 MPa, or 20 to 100 MPa, or 20 to 50 MPa. These values are measured in accordance with ASTM D1708.

Moreover, the circuit material can have at least one of good flame retardancy (for example, a UL-94 V0 rating at 1 millimeter) or a reduced water absorption.

An article can include the circuit material. The article can be for use in a mobile communication device. The article can be for use in a 5G wireless application. The article can be an antenna, for example, a millimeter wavelength antenna. The article can be for use in military applications. The article can be a vehicle (for example, a car or a drone). The article can be a cell phone, laptop computer, tablet, or the like.

The following examples are provided to illustrate the present disclosure. The examples are merely illustrative and are not intended to limit devices made in accordance with the disclosure to the materials, conditions, or process parameters set forth therein.

### EXAMPLES

In the examples, the yield point in the machine direction was determined by ASTM D1708-18, Standard Test Method for Tensile Properties of Plastics by Use of Microtensile Specimens.

The yield point in the cross-machine direction was determined by ASTM D1708-18, Standard Test Method for Tensile Properties of Plastics by Use of Microtensile Specimens.

The permittivity and the dielectric loss were determined by a coaxial airline using the IPC-TM-650 2.5.5.5 Stripline Test for Permittivity and Loss Tangent at X-Band.

The peel strength to copper was measured in accordance with IPC-TM-650, 2.4.8. In the examples, the terminology of a 1 ounce copper foil indicates foil that has a basis weight of 1 ounce per square foot. The equivalent thickness is 1.3 mils (0.0347 millimeters). A ½ ounce copper foil correspondingly has a thickness of 0.01735 millimeters.

The coefficients of thermal expansion in the X- and Y-directions were determined in accordance with IPC-TM-650 2.4.41 from 0 to 150° C.

### Examples 1-9

Composite samples were made, and their resultant mechanical and dielectric properties tested. Example 1 comprised a single layer of liquid crystal polymer, available under the tradename ULTRALAM™ 3850 by Rogers Corporation, where the single layer of the liquid crystal polymer comprised 100 vol % of the liquid crystal polymer based on the total volume of the single layer. This sample was clad with ½ ounce (oz.) (0.65 mils) (14.8 milliliters) very low profile electrodeposited (VLP ED) copper foil. Example 2 comprised a single layer of skive PTFE, where the single layer of the skive PTFE comprised 100 vol % of the skive PTFE based on the total volume of the single layer. Example 3 comprised a single layer of PFA, where the single layer of the PFA comprised 100 vol % of the PFA based on the total volume of the single layer. Example 4 comprised a single layer of composite PFA, where the single layer of PFA comprised 45 vol % of the PFA and 55 volume percent of silica both based on the total volume of the single layer of the composite PFA.

Example 5 was a multilayer stack comprising a layer of biaxially-oriented PFTE located in between two PFA layers of equal thickness. In Example 5, the multilayer stack comprised 87 vol % of the PFA (each sheet forming 43.5 vol %) and 13 volume percent of biaxially-oriented PTFE both based on the total volume of the multilayer stack. Example 6 was a multilayer stack comprising a layer of biaxially-oriented PFTE located in between two composite PFA layers of equal thickness, where the composite PFA layers included equal amounts of silica. In Example 6, the multilayer stack comprised 13 volume percent of biaxially-oriented PTFE, 39.2 vol % of the PFA, and 47.8 vol % of silica, all based on the total volume of the multilayer stack. Example 7 was a multilayer stack comprising a layer of biaxially-oriented PTFE located in between two non-oriented PTFE layers of equal thickness, where the non-oriented PTFE layers included equal amounts of silica. In Example 7, a multilayer stack comprised of 20 vol %, 36 vol % PFA, and 44 vol % silica, all based on the total volume of the multilayer stack. The volume percent of the non-oriented PTFE layer is slightly higher than the biaxially-oriented PTFE layers in Examples 5 and 6. This is due to the commercially availability of thin layers of non-oriented PTFE. In Example 8, the multilayer stack comprised 7 volume percent of biaxially-oriented PTFE, 41.9 vol % of the non-oriented PTFE, and 51.1 vol % of silica, all based on the total volume of the multilayer stack. In Example 9, the multilayer stack where the biaxially-oriented PTFE layer (from Example 8) is replaced with a non-oriented PTFE layer is shown.

The mechanical and dielectric properties of the examples are shown in Table 1. Table 1 shows that the addition of a ceramic filler did not negatively impact bond strength for any of the composites. The addition of a biaxially-oriented PTFE layer substantially improved the MD and CMD yield points compared to those measured from pure films. The incorporation of a biaxially-oriented PTFE reinforcing layer with ceramic filler balances the mechanical properties with the CTE for the composite.

TABLE 1

| Example | 1 | 2 | 3 | 4 | 5 | 6 | 7 | 8 | 9 |
|---|---|---|---|---|---|---|---|---|---|
| LCP (vol %) | 100 | — | — | — | — | — | | — | |
| Biaxially-oriented | — | — | — | — | 13 | 13 | — | 7 | — |
| PTFE (vol %) | | | | | | | | | |
| Non-oriented | — | 100 | — | — | — | — | 20 | 41.9 | 54.2 |
| PTFE (vol %) | | | | | | | | | |
| PFA (vol %) | — | — | 100 | 45 | 87 | 39.2 | 36 | — | — |
| SiO₂ (vol %) | — | — | — | 55 | — | 47.8 | 44 | 51.1 | 45.8 |
| MD yield point | 110 | 20 | 34 | 4 | 69 | 48 | 11 | 26 | 12 |
| (MPa) | | | | | | | | | |
| CMD yield point | 110 | 20 | 34 | 4 | 69 | 41 | 11 | 22 | 12 |
| (MPa) | | | | | | | | | |
| Permittivity at | 3.2 | 2.2 | 2.0 | 3.1 | 2.1 | 2.55 | 2.55 | 2.55 | 2.55 |
| 10 GHz | | | | | | | | | |
| Dielectric loss at | 0.0025 | 0.0001 | 0.0002 | 0.0010 | 0.0010 | 0.0010 | 0.0010 | 0.0010 | 0.0010 |
| 10 GHz | | | | | | | | | |
| Peel strength | — | 4.0 | 4.0 | 4.0 | 4.0 | 4.0 | 4.0 | 4.0 | 4.0 |
| (PLI) (N/mm) | | (0.70) | (0.70) | (0.70) | (0.70) | (0.70) | (0.70) | (0.70) | (0.70) |
| X/YCTE | 17/17 | 210/210 | 210/210 | 100/100 | 200/200 | 70/70 | 70/70 | 70/70 | 70/70 |
| (ppm/° C.) | | | | | | | | | |

Set forth below are non-limiting aspects of the present disclosure.

Aspect 1: A circuit material comprising: a multilayer stack comprising alternating layers of a reinforcing layer and a fluoropolymer layer; wherein the fluoropolymer layer comprises a fluoropolymer other than a biaxially-oriented polytetrafluoroethylene; wherein the reinforcing layer comprises a biaxially-oriented polytetrafluoroethylene; and wherein a conductive layer is in direct physical contact with an outer surface of the multilayer stack.

Aspect 2: The circuit material of Aspect 1, wherein the multilayer stack comprises at least the reinforcing layer located in between a fluoropolymer layer and an additional fluoropolymer layer; wherein at least the fluoropolymer layer is an outermost layer of the multilayer stack; wherein the conductive layer is in direct physical contact with an outer surface of the fluoropolymer layer opposite the reinforcing layer.

Aspect 3: The circuit material of Aspect 1, wherein the multilayer stack comprises at least the fluoropolymer layer located in between the reinforcing layer and an additional reinforcing layer; wherein the reinforcing layer is an outermost layer of the multilayer stack; wherein the conductive layer is in direct physical contact with an outer surface of the reinforcing layer opposite the fluoropolymer layer.

Aspect 4: The circuit material of any of the preceding aspects, wherein the multilayer stack comprises n number of reinforcing layers and (n+1) number of fluoropolymer layers or wherein the multilayer stack comprises n number of fluoropolymer layers and (n+1) number of reinforcing layers, wherein n is 1 to 100.

Aspect 5: The circuit material of any of the preceding aspects, wherein the fluoropolymer has a melting temperature of 320 to 400° C., or 350 to 400° C.

Aspect 6: The circuit material of any of the preceding aspects, wherein the fluoropolymer comprises at least one of poly(chlorotrifluoroethylene) (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene-ethylene-propylene), poly(tetrafluoroethylene-hexafluoropropylene) (also known as fluorinated ethylene-propylene copolymer (FEP)), poly(tetrafluoroethylene-propylene) (also known as fluoroelastomer) (FEPM), poly(tetrafluoroethylene-perfluoropropylene vinyl ether), polyvinylfluoride (PVF), polyvinylidene fluoride (PVDF), poly(vinylidene fluoride-chlorotrifluoroethylene), perfluoropolyether, perfluorosulfonic acid, or perfluoropolyoxetane.

Aspect 7: The circuit material of any of the preceding aspects, wherein the fluoropolymer comprises at least one of a perfluoroalkoxy alkane polymer (PFA) or a polytetrafluoroethylene polymer (PTFE).

Aspect 8: The circuit material of any of the preceding aspects, wherein the multilayer stack comprises more than one fluoropolymer layers and wherein the respective fluoropolymer layers each independently have a thickness of 2 to 70 micrometers, or 2 to 60 micrometers, or 3 to 50 micrometers.

Aspect 9: The circuit material of any of the preceding aspects, wherein the respective layers in the multilayer stack each independently comprise a dielectric filler, optionally in an amount of 10 to 75 vol %, or 30 to 70 vol % based on the total volume of the respective layers.

Aspect 10: The circuit material of Aspect 9, wherein the dielectric filler comprises at least one of silica (for example, fused amorphous silica), wollastonite, solid glass spheres, synthetic glass or ceramic hollow spheres, quartz, boron nitride, aluminum nitride, silicon carbide, alumina trihydrate, magnesia, mica, talc, nanoclay, or magnesium hydroxide; or wherein the dielectric filler comprises at least one of silica or titania.

Aspect 11: The circuit material of any of the preceding aspects, wherein the reinforcing layer comprises a plurality of hollow microspheres.

Aspect 12: The circuit material of any of the preceding aspects, wherein the reinforcing layer is free of a woven or non-woven cloth such as a glass cloth.

Aspect 13: The circuit material of any of the preceding aspects, wherein the reinforcing layer has a thickness of 3 to 60 micrometers, or 10 to 100 micrometers.

Aspect 14: The circuit material of any of the preceding aspects, further comprising a second conductive layer in direct physical contact with an opposing surface of the multilayer stack opposite from the conductive layer.

Aspect 15: The circuit material of any of the preceding aspects, wherein the conductive layer comprises a copper foil.

Aspect 16: The circuit material of any of the preceding aspects, wherein the circuit material has a total thickness of 25 to 150 micrometers, or 25 to 200 micrometers.

Aspect 17: The circuit material of any of the preceding aspects, wherein the circuit material has at least one of: a permittivity of greater than or equal to 2, or 2 to 5 determined in accordance with IPC-TM-650 2.5.5.5 Stripline Test for Permittivity and Loss Tangent at X-Band method at 10 gigahertz; a dielectric loss of less than or equal to 0.003, or 0.0005 to 0.0025 determined in accordance with IPC-TM-650 2.5.5.5 Stripline Test for Permittivity and Loss Tangent at X-Band method at 10 gigahertz; a peel strength to copper of greater than or equal to 0.53 Newtons per millimeter as measured in accordance with IPC test method 650, 2.4.8; a coefficient of thermal expansion in the X- or Y-direction of 15 to 100 ppm/° C. as determined in accordance with IPC-TM-650 2.4.41 from 0 to 150° C.; a yield point in the machine direction of greater than or equal to 20 megapascal, or 20 to 100 megapascal, or 20 to 50 megapascal measured in accordance with ASTM D1708; or a yield point in the cross machine direction of greater than or equal to 20 megapascal, or 20 to 100 megapascal, or 40 to 100 megapascal measured in accordance with ASTM D1708.

Aspect 18: An article comprising the circuit material.

Aspect 19: The article of Aspect 18, wherein the article is a mobile communications device; wherein the article is for use in 5G wireless applications; wherein the article is a millimeter wavelength antenna; or wherein the article in for use in military applications.

Aspect 20: A method of making a circuit material (for example, of any of the preceding aspects) comprising: laminating the multilayer stack and the conductive layer to form the circuit material; or laminating a layered stack comprising the conductive layer and alternative layers of the fluoropolymer layers and the reinforcing layer to form the circuit material.

Aspect 21: The method of Aspect 20, wherein the laminating comprises at least one of: laminating at a lamination temperature of 340 to 400° C., or 350 to 380° C.; laminating at a lamination pressure of 2 to 10 megapascal, or 3 to 8 megapascal; or laminating at a lamination time of 50 to 120 minutes, or 75 to 100 minutes.

The compositions, methods, and articles can alternatively comprise, consist of, or consist essentially of, any appropriate materials, steps, or components herein disclosed. The compositions, methods and articles can additionally, or alternatively, be formulated so as to be devoid, or substantially free, of any materials (or species), steps, or components, that are otherwise not necessary to the achievement of the function or objectives of the compositions, methods, and articles.

As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise. The term “at least one of” means that the list is inclusive of each element individually, as well as combinations of two or more elements of the list, and combinations of at least one element of the list with like elements not named. Also, the term “combination” is inclusive of blends, mixtures, alloys, reaction products, and the like. The term “or” means “and/or” unless clearly indicated otherwise by context. Reference throughout the specification to “an aspect”, “another aspect”, “some aspects”, and so forth, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element or in “direct physical contact with” another element, there are no intervening elements present.

Unless specified to the contrary herein, all test standards are the most recent standard in effect as of the filing date of this application, or, if priority is claimed, the filing date of the earliest priority application in which the test standard appears.

The endpoints of all ranges directed to the same component or property are inclusive of the endpoints, are independently combinable, and include all intermediate points and ranges. For example, ranges of “up to 25 wt %, or 5 to 20 wt %” is inclusive of the endpoints and all intermediate values of the ranges of “5 to 25 wt %,” such as 10 to 23 wt %, etc.).

Unless defined otherwise, technical and scientific terms used herein have the same meaning as is commonly understood by one of skill in the art to which this disclosure belongs.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

What is claimed is:

1. A circuit material comprising:
a multilayer stack comprising alternating layers of a reinforcing layer and a fluoropolymer layer; wherein the reinforcing layer comprises a biaxially-oriented polytetrafluoroethylene, and the fluoropolymer layer comprises a fluoropolymer other than the biaxially-oriented polytetrafluoroethylene; and
a conductive layer in direct physical contact with an outer surface of the multilayer stack.

2. The circuit material of claim 1, wherein the multilayer stack comprises at least the reinforcing layer located in between a fluoropolymer layer and an additional fluoropolymer layer; wherein at least the fluoropolymer layer is an outermost layer of the multilayer stack; wherein the conductive layer is in direct physical contact with an outer surface of the fluoropolymer layer opposite the reinforcing layer.

3. The circuit material of claim 1, wherein the multilayer stack comprises at least the fluoropolymer layer located in between the reinforcing layer and an additional reinforcing layer; wherein the reinforcing layer is an outermost layer of the multilayer stack; wherein the conductive layer is in direct physical contact with an outer surface of the reinforcing layer opposite the fluoropolymer layer.

4. The circuit material of claim 1, wherein the multilayer stack comprises n number of reinforcing layers and (n+1) number of fluoropolymer layers or wherein the multilayer stack comprises n number of fluoropolymer layers and (n+1) number of reinforcing layers, wherein n is 1 to 100.

5. The circuit material of claim 1, wherein the fluoropolymer has a melting temperature of 320 to 400° C.

6. The circuit material of claim 1, wherein the fluoropolymer comprises at least one of poly(chlorotrifluoroethylene) (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene-ethylene-propylene), poly(tetrafluoroethylene-hexafluoropropylene), poly(tetrafluoroethylene-propylene) (FEPM), poly(tetrafluoroethylene-perfluoropropylene vinyl ether), polyvinylfluoride (PVF), polyvinylidene fluoride (PVDF), poly(vinylidene fluoride-chlorotrifluoroethylene), perfluoropolyether, perfluorosulfonic acid, or perfluoropolyoxetane.

7. The circuit material of claim 1, wherein the fluoropolymer comprises at least one of a perfluoroalkoxy alkane polymer (PFA) or polytetrafluoroethylene (PTFE).

8. The circuit material of claim 1, wherein the multilayer stack comprises more than one fluoropolymer layer and wherein the respective fluoropolymer layers each independently have a thickness of 2 to 70 micrometers.

9. The circuit material of claim 1, wherein the respective layers in the multilayer stack each independently comprise a dielectric filler.

10. The circuit material of claim 1, wherein the reinforcing layer comprises a plurality of hollow microspheres or is free of a woven or non-woven cloth.

11. The circuit material of claim 1, wherein the reinforcing layer has a thickness of 3 to 60 micrometers.

12. The circuit material of claim 1, further comprising a second conductive layer in direct physical contact with an opposing surface of the multilayer stack opposite from the conductive layer.

13. The circuit material of claim 1, wherein the conductive layer comprises a copper foil.

14. The circuit material of claim 1, wherein the circuit material has a total thickness of 25 to 150 micrometers.

15. The circuit material of claim 1, wherein the circuit material has at least one of:
a permittivity of greater than or equal to 2 determined in accordance with IPC-TM-650 2.5.5.5 Stripline Test for Permittivity and Loss Tangent at X-Band method at 10 gigahertz;
a dielectric loss of less than or equal to 0.003 determined in accordance with IPC-TM-650 2.5.5.5 Stripline Test for Permittivity and Loss Tangent at X-Band method at 10 gigahertz;
a peel strength to copper of greater than or equal to 0.53 Newtons per millimeter as measured in accordance with IPC test method 650, 2.4.8;
a coefficient of thermal expansion in the X- or Y-direction of 15 to 100 ppm/° C. as determined in accordance with IPC-TM-650 2.4.41 from 0 to 150° C.;
a yield point in the machine direction of greater than or equal to 20 megapascal measured in accordance with ASTM D1708; or
a yield point in the cross machine direction of greater than or equal to 20 megapascal measured in accordance with ASTM D1708.

16. An article comprising the circuit material of claim 1.

17. The article of claim 16, wherein the article is a mobile communications device; wherein the article is for use in 5G wireless applications; wherein the article is a millimeter wavelength antenna; or wherein the article in for use in military applications.

18. A method of making the circuit material of claim 1 comprising:
laminating the multilayer stack and the conductive layer to form the circuit material; or
laminating a layered stack comprising the conductive layer and alternating layers of the fluoropolymer layers and the reinforcing layer to form the circuit material.

19. The method of claim 18, wherein the laminating comprises at least one of:
laminating at a lamination temperature of 340 to 400° C.;
laminating at a lamination pressure of 2 to 10 megapascal; or
laminating at a lamination time of 50 to 120 minutes.

20. A circuit material comprising:
a multilayer stack comprising alternating layers of a reinforcing layer and a fluoropolymer layer; wherein the reinforcing layer comprises a biaxially-oriented polytetrafluoroethylene, and the fluoropolymer layer comprises at least one of a perfluoroalkoxy alkane polymer (PFA) or a non-biaxially-oriented polytetrafluoroethylene (PTFE); and
a conductive layer in direct physical contact with an outer surface of the multilayer stack;
wherein the multilayer stack comprises more than one fluoropolymer layer and wherein the respective fluoropolymer layers each independently have a thickness of 2 to 70 micrometers;
wherein the circuit material has a total thickness of 25 to 150 micrometers; and
wherein the reinforcing layer has a thickness of 3 to 60 micrometers; and wherein the reinforcing layer is free of a woven or non-woven cloth.
